(19) United States
(12) Patent Application Publication
(10) Pub. No.: US 2022/0045162 A1
(43) Pub. Date: Feb. 10, 2022

(54) INTERPOSER STRUCTURE AND METHOD FOR MANUFACTURING THEREOF

(71) Applicant: AP MEMORY TECHNOLOGY CORPORATION, HSINCHU COUNTY (TW)

(72) Inventor: WENLIANG CHEN, HSINCHU COUNTY (TW)

(21) Appl. No.: 17/511,190

(22) Filed: Oct. 26, 2021

Related U.S. Application Data
(63) Continuation-in-part of application No. 17/085,770, filed on Oct. 30, 2020.
Application No. 17/085,770 is a continuation-in-part of application No. 16/609,159, filed on Oct. 28, 2019, now Pat. No. 11,038,012.
(60) Provisional application No. 63/209,923, filed on Jun. 11, 2021.

(51) Int. Cl. H01L 49/02; H01G 4/012; H01G 4/228; H01L 27/06; H01L 27/08; H01L 21/768

(52) U.S. Cl. CPC H01L 28/90; H01G 4/012; H01G 4/228; H01L 27/10829; H01L 27/0805; H01L 21/76802; H01L 27/0688

(57) ABSTRACT

An interposer structure is provided. The interposer structure includes a plurality of interposer units in an array arrangement from a top view perspective. Each of the interposer units includes a first region and a plurality of second regions. The first region has a capacitor structure. Each of the plurality of second regions is free of the capacitor structure. The first region surrounds the plurality of second regions. A method for manufacturing an interposer structure is also provided.

### PRIORITY CLAIM AND CROSS-REFERENCE

This application is a continuation-in-part of pending U.S. application Ser. No. 17/085,770, filed Oct. 30, 2020, which is a continuation-in-part of patented U.S. application Ser. No. 16/609,159, filed Oct. 28, 2019, which is a National Phase of PCT/JP2017/016977, filed Apr. 28, 2017, the entire contents of which is incorporated herein by reference.

This application claims the benefit of prior-filed U.S. provisional application No. 63/209,923, filed Jun. 11, 2021, and incorporates its entirety herein.

### FIELD

The present disclosure relates to an interposer structure and a method for manufacturing thereof, particularly, the disclosed interposer structure includes a plurality of 3D capacitors within a middle-end-of-line (MEOL) structure thereof.

### BACKGROUND

2.5D assembly is a packaging technology for including multiple integrated circuit (IC) dies in a single package. This approach typically has been used for applications where performance and low power are critical. Within 2.5D assembly, communication between IC dies is accomplished using either a silicon or organic interposer. Currently, because the use for high-performance applications and the demand for miniaturization and higher density continues to increase, 2.5D packaging technology utilizing silicon interposers is being widely developed.

### BRIEF DESCRIPTION OF THE DRAWINGS

Aspects of the present disclosure are best understood from the following detailed description when read with the accompanying figures. It is noted that, in accordance with the standard practice in the industry, various structures are not drawn to scale. In fact, the dimensions of the various structures may be arbitrarily increased or reduced for clarity of discussion.

FIG. 1 illustrates a cross-sectional view of an interposer structure according to some embodiments of the present disclosure.

FIG. 2 illustrates a cross-sectional view of a capacitor structure according to some embodiments of the present disclosure.

FIG. 3 illustrates a cross-sectional view of a capacitor structure according to some embodiments of the present disclosure.

FIG. 4A illustrates a top view of a rectangular-array-arrangement of capacitor cells according to some embodiments of the present disclosure.

FIG. 4B illustrates a top view of a hexagonal-array-arrangement of capacitor cells according to some embodiments of the present disclosure.

FIG. 5 illustrates a cross-sectional view of a capacitor structure according to some embodiments of the present disclosure.

FIG. 6 illustrates a cross-sectional view of a capacitor structure according to some embodiments of the present disclosure.

FIG. 7 illustrates a top view layout of an interposer structure according to some embodiments of the present disclosure.

FIG. 8A illustrates a cross-sectional view of a packaged interposer structure according to some embodiments of the present disclosure.

FIG. 8B illustrates a cross-sectional view of a packaged interposer structure according to some embodiments of the present disclosure.

FIG. 9A illustrates a cross-sectional view of a packaged interposer structure according to some embodiments of the present disclosure.

FIG. 9B illustrates a cross-sectional view of a packaged interposer structure according to some embodiments of the present disclosure.

FIG. 9C illustrates a cross-sectional view of a packaged interposer structure according to some embodiments of the present disclosure.

FIG. 9D illustrates a cross-sectional view of a packaged interposer structure according to some embodiments of the present disclosure.

FIGS. 10A to 10I illustrate cross-sectional views of forming a capacitor structure in an interposer structure according to some embodiments of the present disclosure.

FIGS. 11A to 11H illustrate cross-sectional views of forming a packaged interposer structure according to some embodiments of the present disclosure.

FIGS. 12A to 12D illustrate cross-sectional views of forming a packaged interposer structure according to some embodiments of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper”, “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the terms such as “first”, “second” and “third” describe various elements, components, regions, layers and/or sections, these elements, components, regions, layers and/or sections should not be limited by these terms. These terms may be only used to distinguish one element, component, region, layer or section from another. The terms such as “first”, “second”, and “third” when used herein do not imply a sequence or order unless clearly indicated by the context.

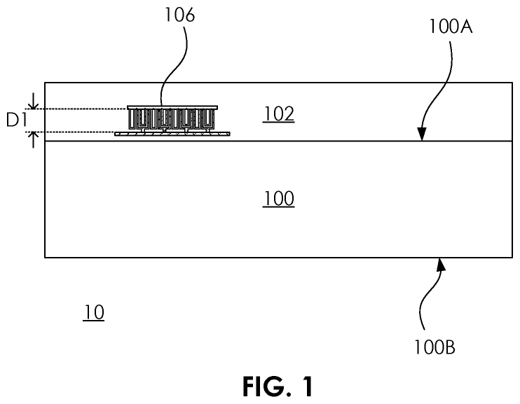

FIG. 1 illustrates an interposer structure that includes a plurality of 3D capacitors embedded in a middle-end-of-line (MOL/MEOL) structure thereof. As shown in the figure, the interposer structure 10 includes a substrate portion 100 having a front side 100A, and a back side 100B opposite to the front side 100A. The interposer structure 10 further includes a wiring portion 102 over the front side 100A of the substrate portion 100.

In some embodiments, the substrate portion 100 is a semiconductor wafer to accommodate semiconductor device components. In some embodiments, the substrate portion 100 is an insulator substrate to minimize parasitic resistance and inductance. In some embodiments, the substrate portion 100 is composed of silicon or glass. In some embodiments, the substrate portion 100 includes active or passive device components therein, for example, the device components may include memory structure or power regulator.

An existing capacitor structure may be formed in the substrate portion of an interposer structure, where a plurality of trenches may be formed in the substrate portion 100. Each of the trenches (or so-called deep trench) can have a depth in a range of from about 10 μm to about 30 μm, or from about 20 μm to about 30 μm. However, the depth of the trenches to some extent weakens the mechanical strength of the substrate portion of the interposer structure. On the other hand, in the scenario where the substrate portion is made of insulative material, the formation of the deep trenches is more economically inefficient compared to the semiconductor counterpart and thus unattractive.

Therefore, in one aspect, the present disclosure aims to alter the structure of the layer over the substrate portion 100 of the interposer structure 10, in order to solve the problems created by the existing deep trench capacitor structure and effectively utilize the space in the interposer structure 10. Still referring to FIG. 1, the wiring portion 102 is located over the front side 100A of the substrate portion 100. The wiring portion 102 is the structure within a semiconductor structure that be formed prior to the formation of a first metal layer (M1); that is, the wiring portion 102 is called a middle-end-of-line (MOL/MEOL) structure, which is formed prior to the formation of a back-end-of-line (BEOL) structure. In some embodiments, the wiring portion 102 is made of dielectric material, which may be referred to as a pre-metal dielectric (PMD). In other words, the wiring portion 102 can be distinguished from the substrate portion 100 therebelow and the BEOL structure thereon by a number of process parameters, such as the choice of the fundamental material, or the choice of the metal used. For instance, the material of the wiring portion 102 can be low-k dielectric material that with a small dielectric constant relative to silicon dioxide, and thus can be distinguished from the material of the substrate portion 100; likewise, the metal usually used in the wiring portion 102 for electrical connect is tungsten, while the metal usually used in the BEOL structure is copper. These are several exemplary approaches to distinguish the stacked layers in the interposer structure 10, but the present embodiments are not be limited thereto.

In some embodiments, a plurality of the capacitor structures 106 are embedded in the wiring portion 102. In some embodiments, the capacitor structure 106 can be a 3D metal insulator metal (MIM) capacitor, while such out-of-plane dimension can be advantageously used to increase effective MIM area and related capacitance density. In some embodiments, the capacitor structure 106 in the present disclosure may have a very high density, for example, higher than about 1 μF/mm². In some embodiments, the 3D capacitor can be a cylinder capacitor.

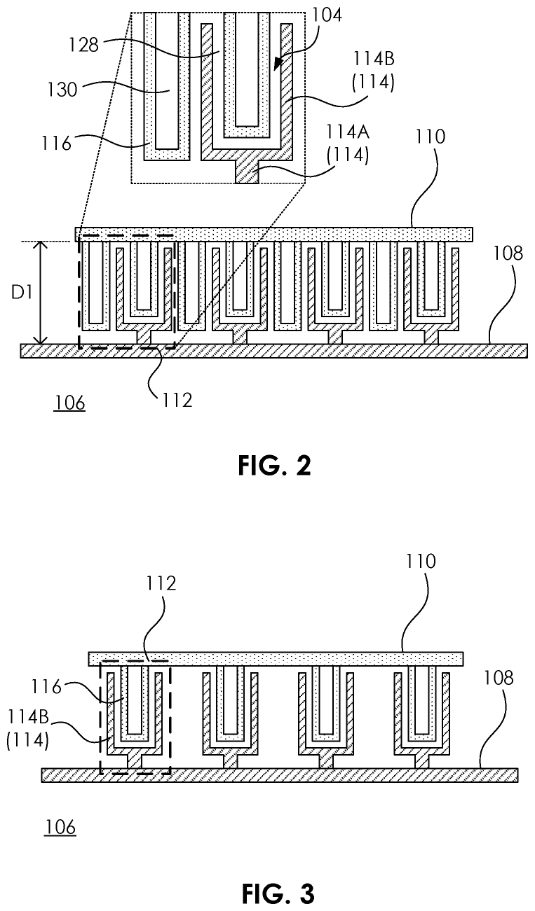

As shown in FIG. 2, in some embodiments, each of the capacitor structures 106 includes a bottom metal plate 108, a top metal plate 110 over the bottom metal plate 108, and a plurality of capacitor cells 112 are formed between the bottom metal plate 108 and the top metal plate 110. In some embodiments, a distance D1 between the bottom metal plate 108 and the top metal plate 110 is in a range of from about 1 μm to about 2 μm, which is much thinner than the aforementioned active or passive device component examples that formed in the deep trenches of the substrate portion 100.

The configuration of the capacitor cells 112 can have a crown-type capacitive structure or a concave-type capacitive structure. As illustrated in FIG. 2, in the embodiment that each of the capacitor cells 112 are formed in crown type, the capacitor cell 112 includes a first conductor film 114 and a second conductor film 116 stacked between the bottom metal plate 108 and the top metal plate 110. In some embodiments, the first conductor film 114 includes a first portion 114A connected to the bottom metal plate 108, and a second portion 114B connected to the first portion 114A and extending toward the top metal plate 110 from the bottom metal plate 108. In some embodiments, the second conductor film 116 is disposed adjacent to the first conductor film 114 and connected to the top metal plate 110, and extending toward the bottom metal plate 108 from the top metal plate 110. In some embodiments, the second conductor film 116 is vertically interleaving with the second portion 114B of the first conductor film 114. For instance, as the cross-sectional view shown in the figure, the second conductor film 116 is located adjacent to the inner and outer sides of an accommodated space 104. This accommodated space 104 is rounded by the first conductor film 114.

Moreover, the capacitor cell 112 further includes a first insulating film 128 for isolating the first conductor film 114 and the second conductor film 116. In other words, the MIM feature of the capacitor structure 106 is performed by the stack of the first conductor film 114, the first insulating film 128, and the second conductor film 116. As shown in FIG. 2, in some embodiments, a second insulating film 130 can optionally be utilized to fill the space between the second conductor film 116 and the top metal plate 110. In some embodiments, the first insulating film 128 and the second insulating film 130 are composed of high-k dielectric material. For example, the high-k dielectric material may contain at least one of the oxides of Lanthanum, Hafnium, and Zirconium.

As shown in FIG. 3, in other embodiments, the capacitor cells 112 are formed in concave type, the capacitor cell 112 also includes the first conductor film 114 and the second conductor film 116 stacked between the bottom metal plate 108 and the top metal plate 110. In such embodiments, the second conductor film 116 is also formed adjacent to the first conductor film 114 and connected to the top metal plate 110, and extending toward the bottom metal plate 108 from the top metal plate 110. Comparing to the crown type shown in FIG. 2, the second conductor film 116 is laterally surrounded by the second portion 114B of the first conductor film 114 in each of the concave type capacitor cells 112, instead of entirely adjacent to inner and outer sides of the accommodated space 104 rounded by the first conductor film 114.

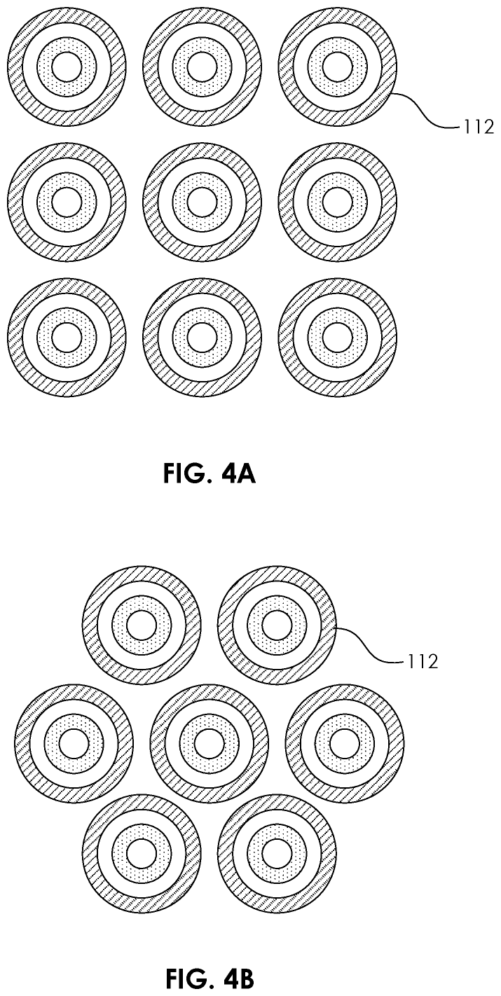

FIGS. 4A and 4B are top view diagrams illustrating a plurality of capacitor cells 112 (concave type) according to some embodiments of the present disclosure. As shown in FIG. 4A, in some embodiments, the plurality of capacitor cells 112 can be arranged to be a rectangular array between the metal plates (i.e., the bottom metal plate 108 and the top metal plate 110 previously shown in FIGS. 2 and 3) of the capacitor from a top view perspective. Alternatively, in other embodiments, as shown in FIG. 4B, the capacitor cells 112 can be arranged to be a hexagonal array between the metal plates of the capacitor from a top view perspective. Generally, the hexagonal-array-arrangement may provide a higher density of the capacitor cells 112. The arrangement of the capacitor cells 112 of the present disclosure is not limited to the embodiments shown in FIGS. 4A and 4B, because the capacitor cells 112 may be arranged to be any symmetrical shape depending on the requirement.

Referring to the embodiment previously shown in FIGS. 1 to 3, the capacitor structure 106 embedded in the wiring portion 102 does not have metal contacts directly over and in contact with the bottom metal plate 108 and the top metal plate 110. In the circumstance that the interposer structures 10 are provided to the downstream manufacturers for further processing, such as forming an interconnect portion over the wiring portion 102, which will be discussed later, there would have a certain degree of difficulty to make the metal contacts perfectly land on the surfaces of the bottom metal plate 108 and the top metal plate 110.

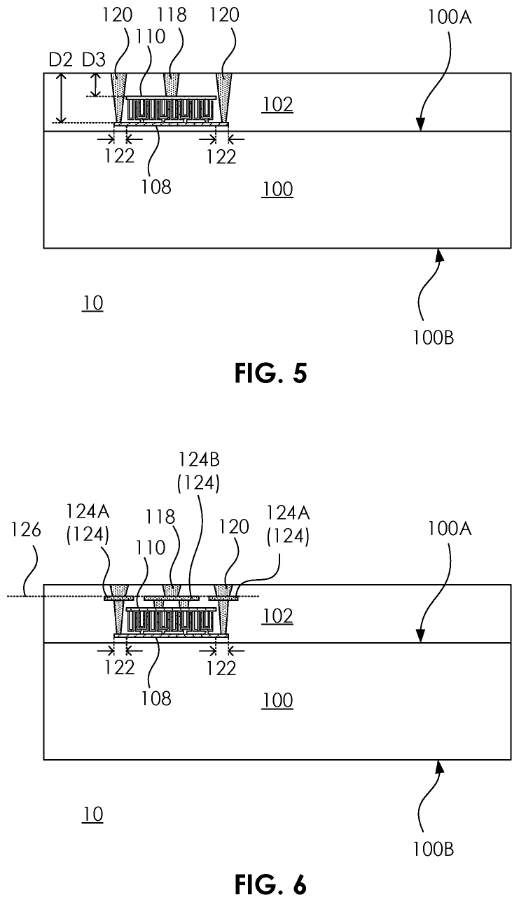

To be more detailed, referring to the embodiment shown in FIG. 5, the interposer structure 10 may further include a first metal contact 118 and a second metal contact 120. The first metal contact 118 is directly landed on the top surface of the top metal plate 110, and the second metal contact 120 is directly landed on an uncovered region 122 of the bottom metal plate 108 that is free from being covered by the top metal plate 110. In such embodiment, the first metal contact 118 and the second metal contact 120 are different in vertical lengths.

The distance differences D2, D3 between the bottom and top metal plates 108, 110 and the top surface of the wiring portion 102 may induce the landing of first and second metal contacts 118, 120 comparatively complicated. Particularly, the aforementioned downstream manufacturers have to accurately position the uncovered region 122 of the bottom metal plate 108 that is free from being covered by the top metal plate 110, while the area of such uncovered region 122 is extremely smaller than the area of the top surface of the metal plate 110, and therefore, the position operation could be failed and unwanted shifting of the metal contact may occur.

Accordingly, in other embodiments, the present disclosure may provide the interposer structure 10 further includes a plurality of capacitor electrode structures 124 over the bottom metal plate 108 and the top metal plate 110. As shown in FIG. 6, the interposer structure 10 may include a first capacitor electrode structure 124A in contact with the uncovered region 122 of the bottom metal plate 108 and a second capacitor electrode structure 124B in contact with the top surface of the top metal plate 110. In such embodiments, the first capacitor electrode structure 124A and the second capacitor electrode structure 124B may provide a coplanar contacting surface 126 over the capacitor structure 106 for the contact landing of the metal contacts. That is, in such embodiments, the first metal contact 118 and the second metal contact 120 are substantially identical in vertical lengths. In some embodiments, each of the first capacitor electrode structures 124A or the second capacitor electrode structure 124B includes a combination of a capacitor contact and a capacitor pad. In some embodiments, the height of the first capacitor electrode structure 124A is greater than the height of the second capacitor electrode structure 124B.

On the other hand, the first capacitor electrode structure 124A may have a top area larger than the area of the uncovered region 122 of the bottom metal plate 108, and thus the landing of the first metal contact 118 can be easier and the yield of the product can be improved.

In some embodiments, other than the capacitor structures 106, the interposer structure 10 may further include a memory structure in the wiring portion 102 since both the capacitor structures 106 and the memory structure can be formed by a compatible DRAM process, which means the capacitor structures 106 and the memory structure can be formed by semiconductor processes that are compatible to general-purpose DRAM fabrication processes, such that it is possible to realize high density, thickness reduction, and low cost. In general-purpose DRAM semiconductor process technology, a capacitor can be formed without using a structure formed below the surface of a silicon substrate like a trench capacitor and is very suitable to reduce the vertical dimension of the capacitor device. Furthermore, process development costs can be reduced by diverting general-purpose DRAM semiconductor process technology. The memory structure that formed in the wiring portion 102 may be utilized as the caches of the dies disposed over the interposer structure 10.

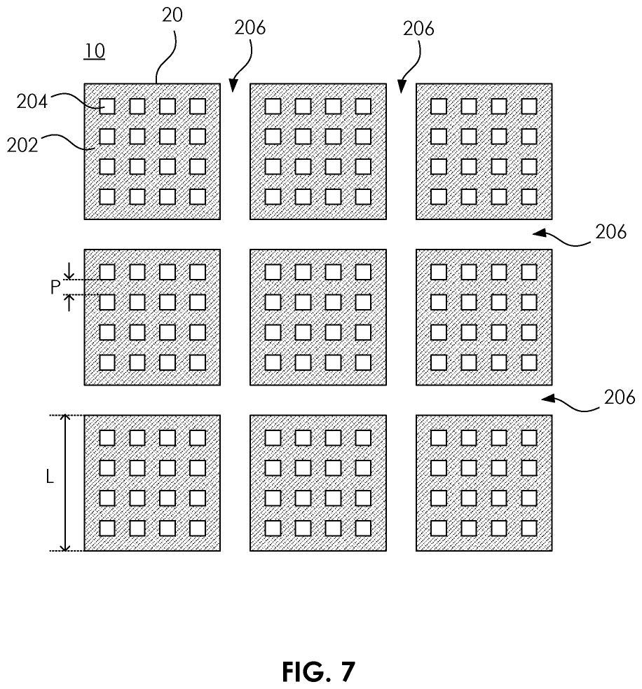

FIG. 7 is a top view layout of an interposer structure 10 according to some embodiments of the present disclosure. In the embodiment shown in FIG. 7, the interposer structure 10 includes a plurality of interposer units 20 in an array arrangement from a top view perspective. Each of the interposer units 20 includes a first region 202 and a plurality of second regions 204. In some embodiments, the first region 202 may have a mesh pattern from a top view perspective because the shapes of the second regions 204 are substantially the same, and the second regions 204 are arranged in an array or be distributed within the interposer unit 20 in a periodic manner. In some embodiments, the first region 202 surrounds each and every of the plurality of second region 204. In some embodiments, the interposer structure 10 is in a form of a semiconductor wafer bearing the plurality of interposer units 20 as illustrated in FIG. 7.

The first region 202 of the interposer unit 20 is utilized to accommodate the capacitor structures 106, while each of the second regions 204 is reserved for forming a through via, for example, a through silicon via (TSV), therein. That is, each of the second regions 204 is configured to accommodate a through via penetrating the interposer structure. Since there are only some regions (i.e., the second region 204) be reserved for forming TSVs, the rest part of the interposer unit 20 can be filled with 3D capacitors to effectively use the space of the wiring portion 102 (i.e., the MEOL structure) of the interposer unit 20. In some embodiments, the capacitor structures 106 may cover more than half of the interposer structure 10 from a top view perspective. In some embodiments, an area ratio of the first region 202 in one of the interposer units 20 is more than 50%. In some embodiments, an area ratio of the first region 202 in one of the interposer units 20 is in a range of from about 50% to about 80%.

In some embodiments, a pitch P between adjacent second regions 204 is less than about 100 μm. In some embodiments, a length L on a side of one of the interposer units 20 is in a range of from about 0.5 to 1 mm. Furthermore, as illustrated in FIG. 7, the adjacent interposer units 20 are spaced apart by scribe line 206. The scribe lines 206 allows the arbitrary grouping of any numbers of the interposer units 20 by dicing along the suitable scribe lines 206, for example, a 2 by 2 interposer units 20 may be diced to be bonded to a first type of semiconductor die or die stack, and a 4 by 4 interposer units 20 may be diced to be bonded to a second type of semiconductor die or die stack. The array arrangement of the interposer units 20 provides a modularized product geometry suitable for various interposer applications. The width of the scribe lines 206 is wide enough to be diced into a plurality of block units, while each of the block units includes one or more interposer units 20. The multiple interposer units 20 in a single block unit can be arranged in a row or an array. The size of the block unit is depending on the numbers and the sizes of integrated circuit dies that will be bumped over a single block unit. In other words, because the size of an interposer structure is highly related to the purpose of 2.5D packaging technique, the IC packaging industry may utilize the interposer structure 10 disclosed in the present disclosure flexibly by dicing the interposer structure 10 to the desired size that fit the requirement of IC packages.

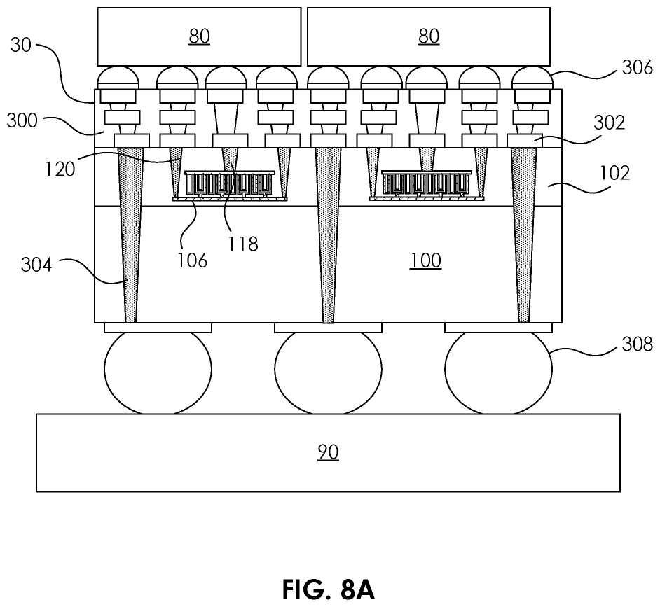

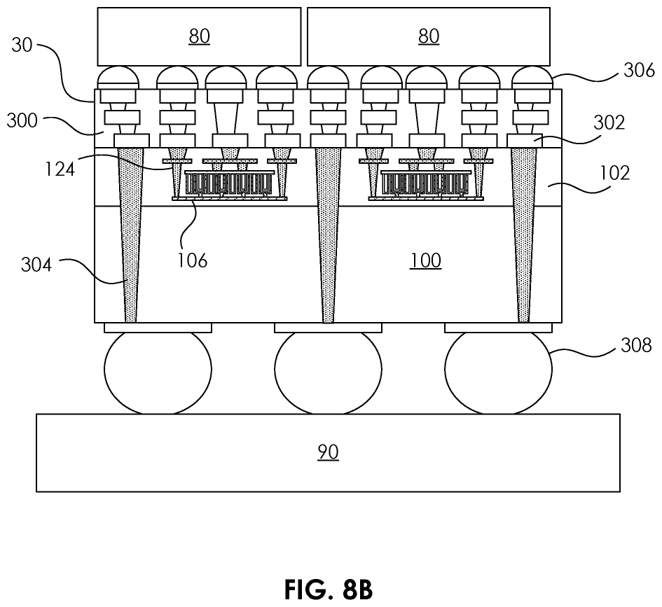

Referring to FIG. 8A, in the circumstances that the interposer structure is applied in a semiconductor structure after being processed by packaging techniques, the interposer structure 30 may include an interconnect portion 300 over the wiring portion 102. Thereby, the capacitor structure 106 is located between the substrate portion 100 and the interconnect portion 300 of the interposer structure 30 from a cross sectional view perspective. Generally, the interconnect portion 300 is configured to bond with one or more semiconductor dies 80 over the interposer structure 30, whereas the substrate portion 100 is configured to bond with a package substrate 90 below the interposer structure 30. The semiconductor dies 80 over the interposer structure 30 has a critical dimension smaller than a critical dimension of the interposer structure 30. In some embodiments, the interconnect portion 300 is called a BEOL structure over the MEOL structure, and therefore the interconnect portion 300 includes a first metal layer (M1) 302 that is directly in contact with a top surface of the wiring portion 102. Within the interconnect portion 300, there may include more metal levels other than the first metal layer 302, such as M2, M3, etc. Those metal levels or metal layers are electrically coupled by metal vias, and the topmost metal layer may provide bonding sites for chip-to-package connections. In another way, in some embodiments, there are a plurality of metal wires formed within the interconnect portion 300, wherein each of the metal wires may be composed of metal vias and one or more metal layers (i.e., M1, M2, M3, etc.), and the arrangement of the metal wires may be used to determine the connections among the semiconductor dies 80 and the package substrate 90.

Moreover, as illustrated in FIG. 8A, the interposer structure 30 may include one or more through vias 304, or called through silicon vias (TSVs), which penetrate the substrate portion 100 and the wiring portion 102 to electrically couple the semiconductor dies 80 and the package substrate 90. The TSVs 304 and the capacitor structures 106 are staggered in the wiring portion 102. As previously mentioned and illustrated in FIG. 7, each of the second regions 204 are reserved for forming a TSV therein, and therefore the capacitor structures 106 embedded in the wiring portion 102 do not interfere with the wiring in the interposer structure 30.

Still referring to FIG. 8A, the first metal layer 302 is not only electrically coupled to the TSVs 304, but also electrically coupled to the capacitor structures 106. In some embodiments, the capacitor structures 106 may be electrically coupled to the first metal layer 302 through the first metal contact 118 and the second metal contact 120 over the top metal plate 110 and the bottom metal plate 108 of the capacitor structure 106, respectively (see the labels in FIG. 5). In the embodiment shown in FIG. 8A, the first metal contact 118 and the second metal contact 120 are different in vertical lengths since there is no capacitor electrode structure pre-formed in the wiring portion 102 to provide a plain contacting surface for the first metal contact 118 and the second metal contact 120.

In contrast, referring to other embodiments shown in FIG. 8B, the capacitor electrode structure 124 is formed in the wiring portion 102 to reduce the difficulty of the landing of the first metal contact 118 and the second metal contact 120 over the capacitor structure 106. The details of the capacitor electrode structure 124 may refer to the description previously shown in FIG. 6 and omitted here for brevity.

As shown in FIGS. 8A and 8B, the interconnect portion 300 may be electrically connected to the semiconductor dies 80 over the interposer structure 30 through a first conductive terminal 306. The first conductive terminal 306 may include a plurality of conductive pillars (e.g., Cu pillars) or other suitable forms of bumping connections, wherein the first conductive terminal 306 may be surrounded by suitable protection or passivation materials (not shown in the figure). In other embodiments, a hybrid bonding structure may be implemented to electrically connect the interconnect portion 300 and the semiconductor dies 80. At the opposite surface of the interposer structure 30, a second conductive terminal 308 may be implemented between the package substrate 90 and the substrate portion 100 of the interposer structure 30. In some embodiment, the second conductive terminal 308 may include C4 bumps, solder balls, or the like. In some embodiments, the semiconductor dies 80 may include system on a chip (SOC), high bandwidth memory (HBM), logic die, memory die, graphics processing unit (GPU), central processing unit (CPU), or the like. In some embodiments, the semiconductor dies 80 can be replaced with chiplets. In some embodiments, an interconnect portion (not shown) of the semiconductor dies 80 has a wiring dimension smaller than a wiring dimension of the interconnect portion 300 of the interposer structure 30.

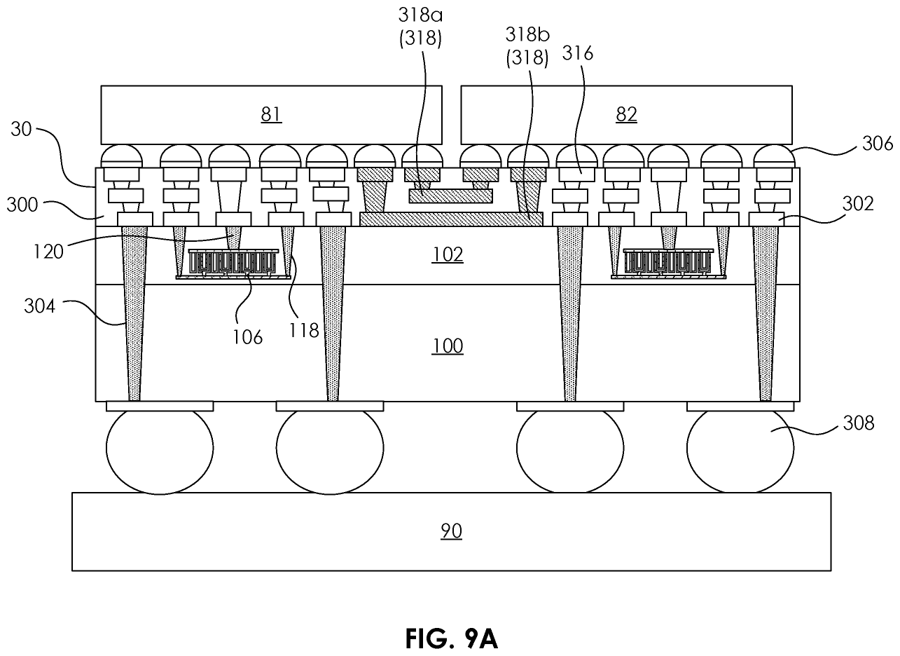

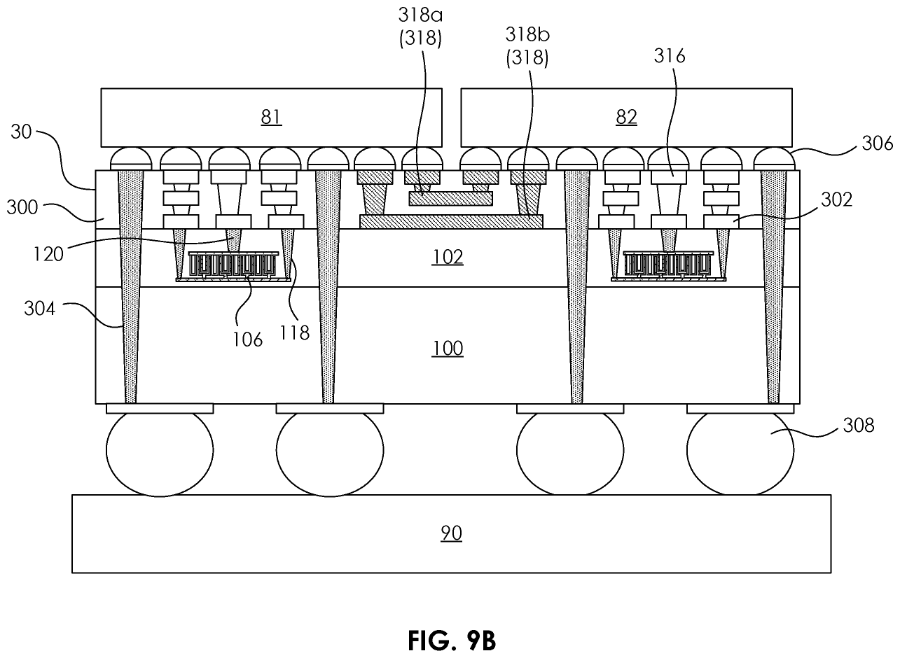

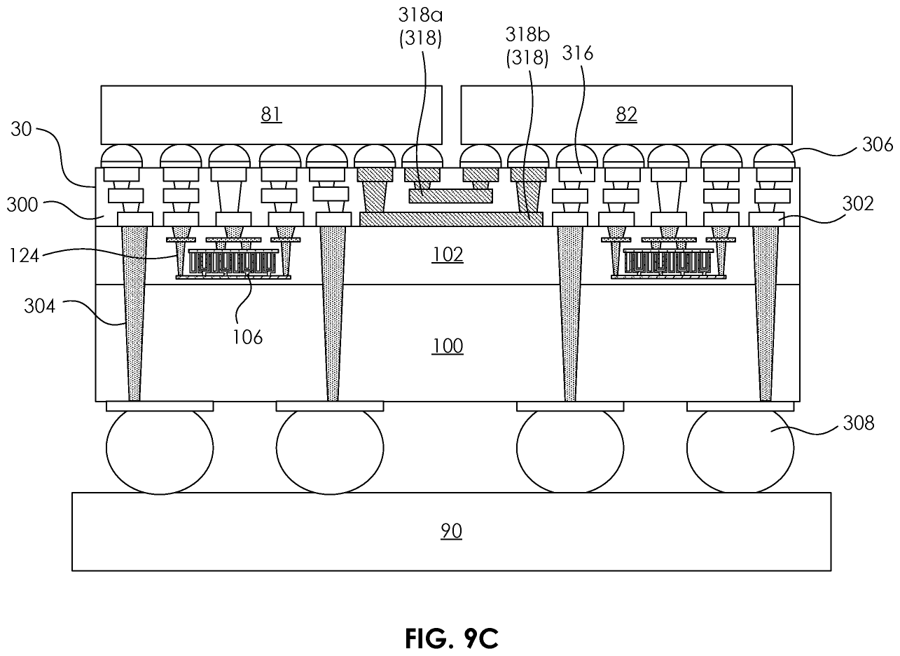

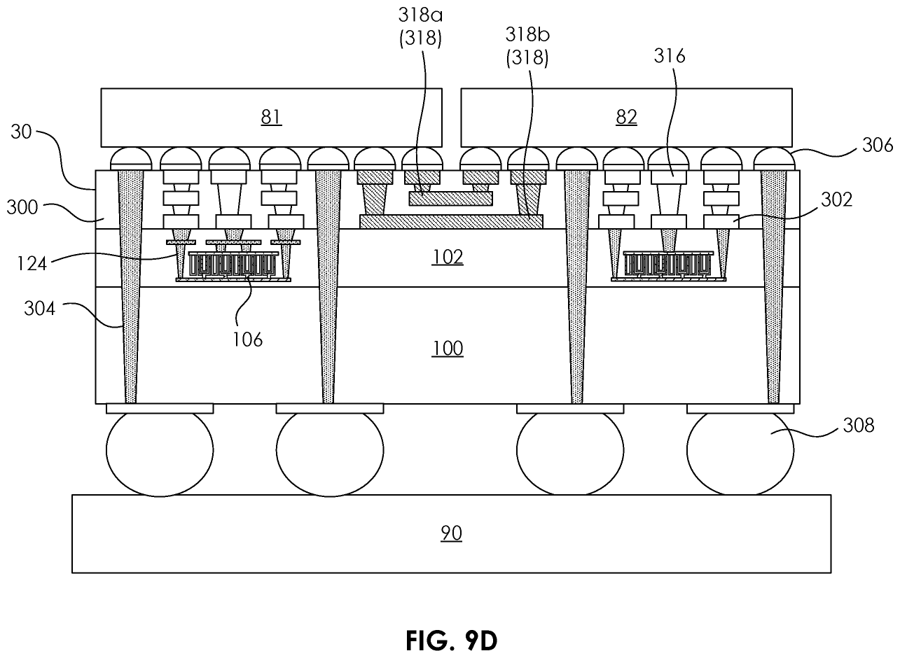

As shown in FIG. 9A, in some embodiments, the interconnect portion 300 includes a first metal wire 316. The first metal wire 316 includes a portion of the first metal layer 302, and the first metal wire 316 is electrically coupled to the capacitor structure 106. In some embodiments, the first metal wire 316 is disposed over the TSV 304, and the first metal wire 316 is electrically coupled to the TSV 304 and the capacitor structure 106.

In some embodiments, a first semiconductor die 81 and a second semiconductor die 82 may be bonded over the interposer structure 30. In some embodiments, the first semiconductor die 81 is identical to the second semiconductor die 82. In other embodiments, the first semiconductor die 81 is different from the second semiconductor die 82. The first semiconductor die 81 can be electrically coupled to the second semiconductor die 82 through the interconnect portion 300. As shown in FIG. 9A, in some embodiments, the interconnect portion 300 includes a second metal wire 318 in the interconnect portion 300, and the second metal wire 318 is electrically connected to the first semiconductor die 81 and the second semiconductor die 82. In some embodiments, some of the second metal wires 318 may include a portion of the first metal layer 302, such as the second metal wire 318b in the figure. In other examples, some of the second metal wires 318a may entirely over the first metal layer 302. In some embodiments, the second metal wire 318 is disconnected from the first metal wire 316 or the TSV 304. In other words, the second metal wire 318 is utilized to transmit electrical signal between the first semiconductor die 81 and the second semiconductor die 82 without detouring to the TSV 304 or the capacitor structure 106. As shown in FIG. 9A, the wiring portion 102 directly below the second metal wire 318 is free from having the capacitor structure 106. The staggered arrangement of the second metal wire 318 and the capacitor structure 106 may reduce the interference of the signal in the second metal wire 318 caused by the underlying capacitor structure 106. However, this is not a limitation of the embodiments. The capacitor structure 106 in the wiring portion 102 may also be formed directly below the second metal wire 318 when the requirement of interference of the signal in the second metal wire 318 caused by the underlying capacitor structure 106 is relatively loose.

As shown in FIG. 9B, in some embodiments, the TSVs 304 may penetrate the substrate portion 100, the wiring portion 102, and the interconnect portion 300, and the TSVs 304 are disconnected from the first metal wire 316 and the second metal wire 318. In such embodiments, the TSVs 304 are formed after the forming the interconnect portion 300 over the wiring portion 102. The top surfaces of the first metal wire 316, the second metal wire 318, and the through vias 304 are all aligned at the top surface of the interconnect portion 300. Furthermore, in such embodiments, the first metal layer 302 is not over the TSVs 304, and thus the TSVs 304 are disconnected from the first metal layer 302.

FIGS. 9A and 9B are used to illustrate the features regarding various metal wires designed for dedicated signal transmission purposes, and an extended through via disconnected from other routings which allows high speed signal transmission. In some embodiments, as shown in FIGS. 9C and 9D, the capacitor structure 106 with the capacitor electrode structure 124 may be applied in the architecture previously described in FIGS. 9A and 9B. The detailed description of the capacitor structure 106 with the capacitor electrode structure 124 may refer to the content addressing FIGS. 6 and 8B, and is omitted here for brevity.

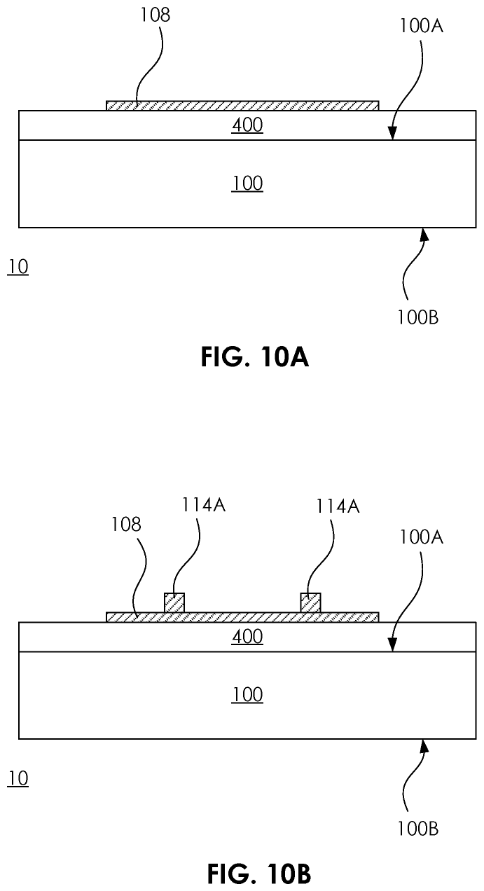

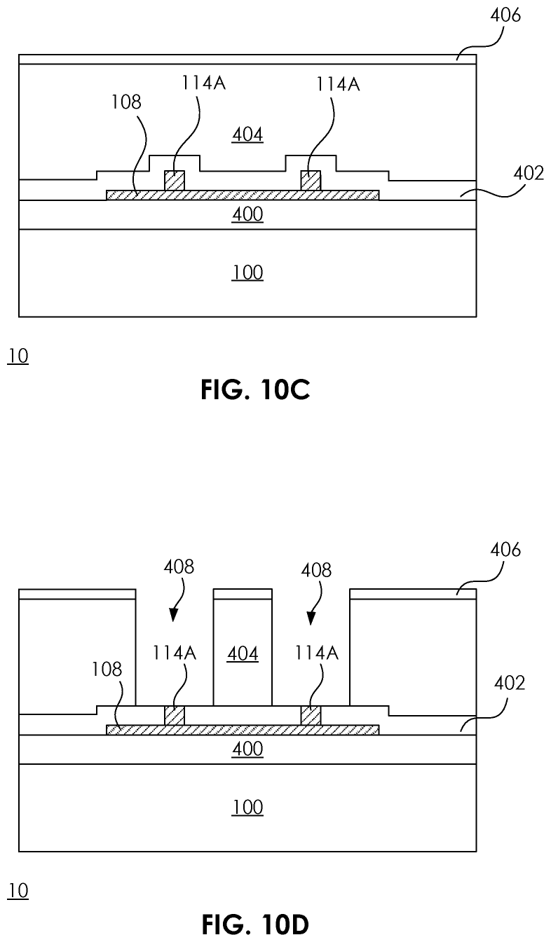

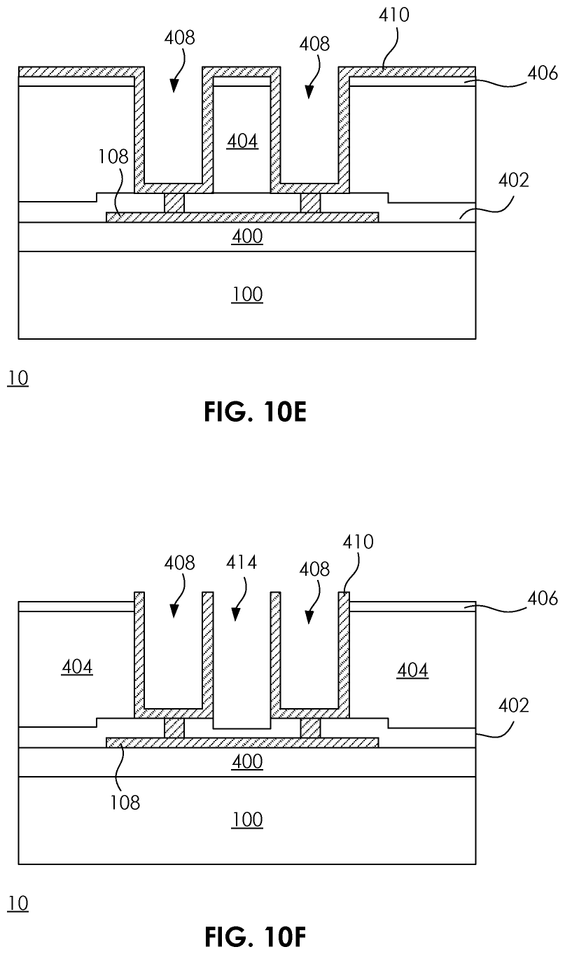

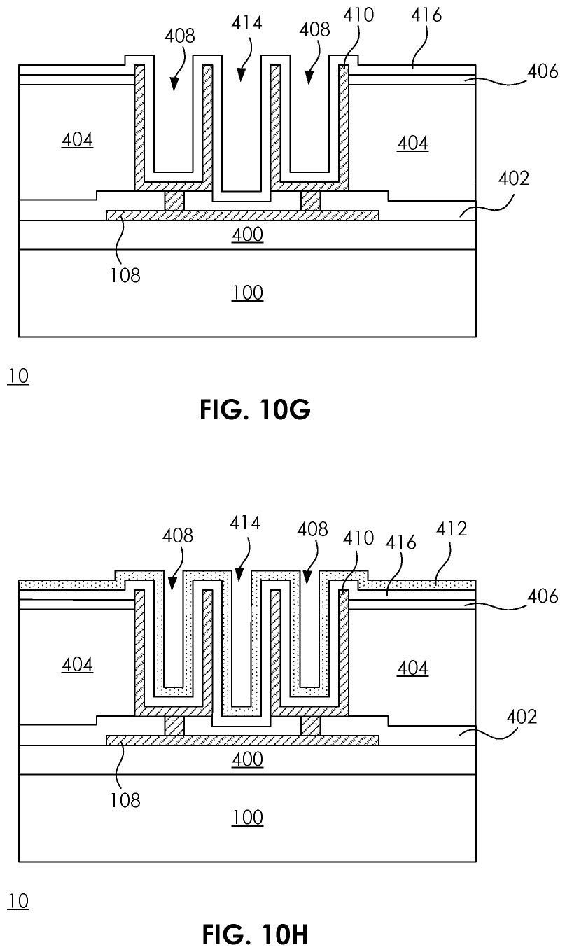

In manufacturing the interposer structure 10 as shown in FIG. 1, particularly, the operations to form the capacitor structure 106 in the wiring portion 102, may refer to FIGS. 10A to 10I. As shown in FIG. 10A, a semiconductor substrate or a glass substrate may be received as the substrate portion 100, and the front side 100A of the substrate portion 100 is covered by a first PMD layer 400, and a bottom metal plate 108 is formed over the first PMD layer 400. The PMD layer 400 may include low-k dielectric material.

Referring to FIG. 10B, a plurality of metal bases may be formed over the top surface of the bottom metal plate 108 through deposition and patterning operations. These metal bases are identical to the first portions 114A of the first conductor film 114 as previously shown in FIG. 6. The first portions 114A may elevate the later-formed second portions 114B of the first conductor film 114 spaced apart from the bottom metal plate 108, and thus a bottom of the second portion 114B of the first conductor film 114 can laterally be aligned to a bottom of the later-formed second conductor film 116.

Referring to FIG. 10C, a first nitride film 402, a second PMD layer 404, and a second nitride film 406 are formed over the bottom metal plate 108 subsequently. The second nitride film 406 is formed to prevent the crown-type capacitive structure from falling in a later operation. Next, referring to FIG. 10D, the stack of the first nitride film 402, the second PMD layer 404, and the second nitride film 406 are patterned to form a plurality of openings 408, and top surfaces of the first portions 114A are exposed accordingly. Then, referring to FIG. 10E, a conductor layer 410 is formed over the second nitride film 406 and covers the profiles of the openings 408. The conductor layer 410 is for forming the second portion 114B of the first conductor film 114.

Referring to FIG. 10F, the conductor layer 410 is patterned to remove some top portions of the conductor layer 410. The patterns in this operation may determine which type of capacitor structure is going to form. For example, the embodiment shown in FIG. 10F can be used to form a crown type capacitor structure 106 since there is an opening 414 between the vertical portions of the conductor layer 410 formed by etching, whereas in another embodiment, which with less second PMD layer 404 between the vertical portions of the conductor layer 410 is not removed, a concave type capacitor structure 106 can be formed since there is no opening 414. The present disclosure using the embodiment of forming crown type capacitor structure 106 as an example. In fact, other operations for forming the concave-type capacitor structure 106 are substantially similar to the operations for forming the crown-type capacitor structure, thus they are omitted here for brevity.

Afterward, as shown in FIG. 10G, an insulating film 416 is formed over the conductor layer 410. The insulating film 416 may include high-k dielectric materials such as the oxides of Lanthanum, Hafnium, and Zirconium. Referring to FIG. 10H, another conductor layer 412 is formed over the insulating film 416. The conductor layer 412 is substantially identical with the second conductor film 116, which is adjacent to the first conductor film 114 and connected to the top metal plate 110 and extending toward the bottom metal plate 108 from the top metal plate 110. Accordingly, a MIM capacitor structure is achieved by subsequently stacking the conductor layer 410, the insulating film 416, and the conductor layer 412, such as the example shown in FIG. 10I, after implementing a planarization operation.

In some embodiments, before the operation of covering the capacitor structures 106 by using PMD materials to embed the capacitor structures 106 in the wiring portion 102, a plurality of capacitor electrode structures 124 may be formed over the capacitor structures 106 for the landing of the metal contacts in the later operations. In other embodiments that without having capacitor electrode structures, the PMD materials may be formed over the capacitor structures 106 to make them embedded in the wiring portion 102.

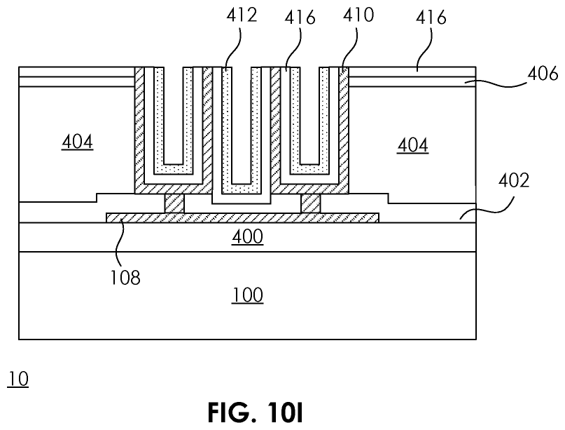

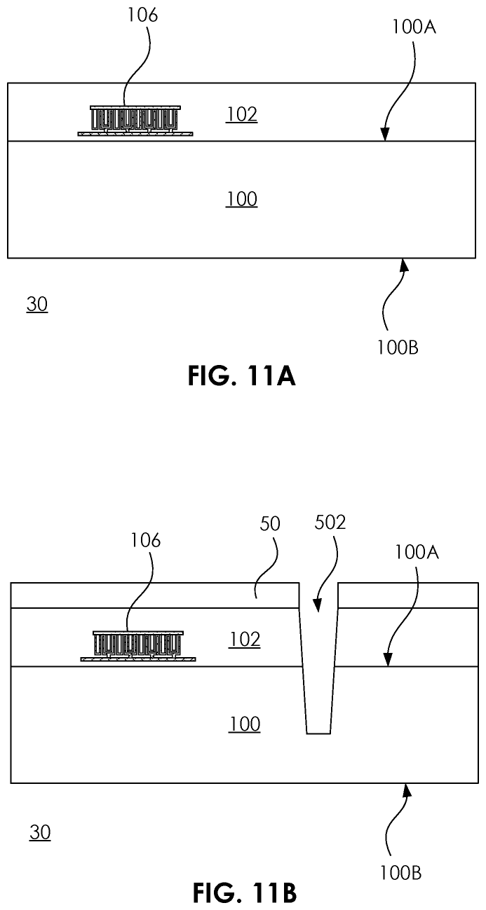

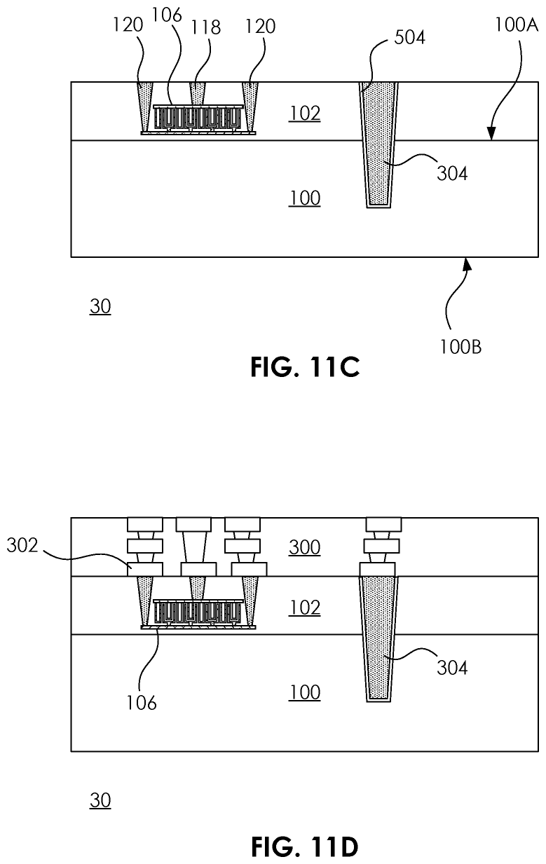

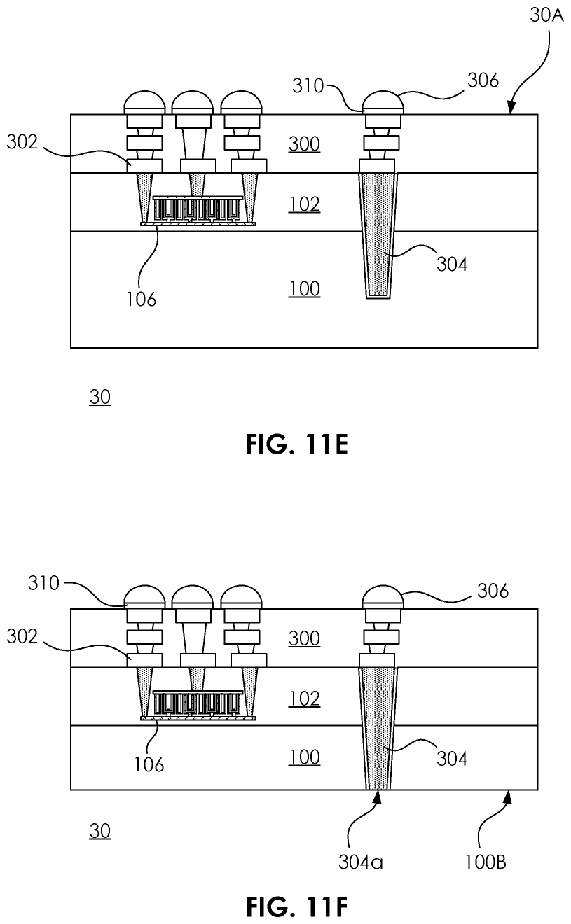

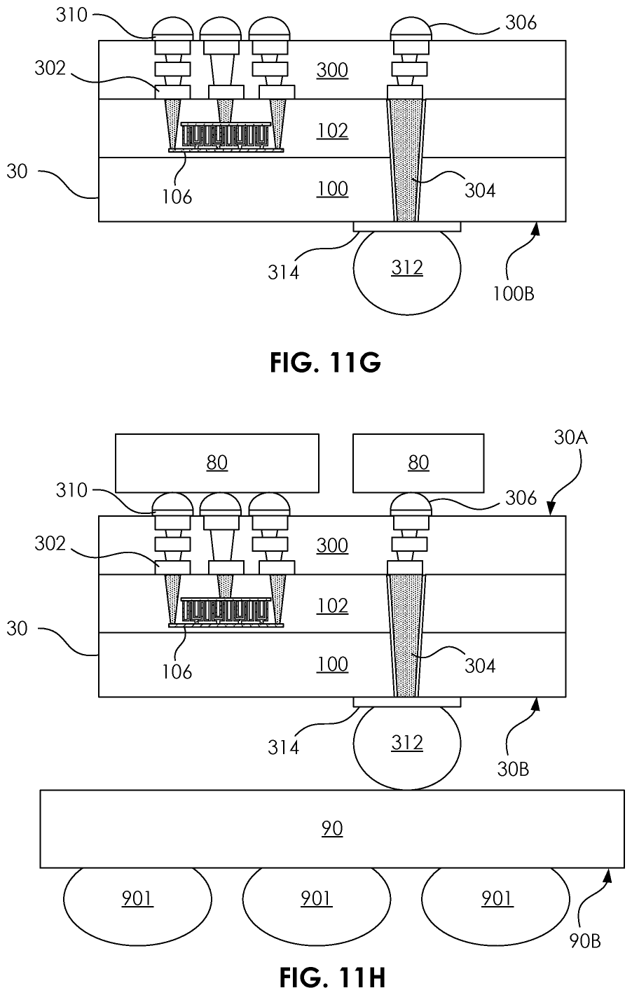

In manufacturing the interposer structure 30 that is packaged with the semiconductor dies 80 (or the first and the second semiconductor dies 81, 82) and package substrate 90 as previously shown in FIGS. 8A, 8B, 9A, and 9C, the operations may refer to the embodiment illustrated in FIGS. 11A to 11H. As shown in FIGS. 11A to 11C, the interposer structure 30 is received after forming the wiring portion 102 over the front side 100A of the substrate portion 100, and the capacitor structure 106 is formed within the wiring portion 102 during forming the wiring portion 102. A photoresist layer 50 may be disposed over the wiring portion 102. By implementing a TSV etching operation, a trench 502 can be formed. As shown in the figure, the trench 502 penetrates the wiring portion 102 and extends toward the substrate portion 100. The position of the trench 502 bypasses the capacitor structure 106 and so that the later formed through vias can free from overlap with the capacitor structure 106. The trench 502 may be subsequently filled by a via filling operation. In some embodiments, an oxide liner 504 may be formed in the trench 502 prior to filling the conductive materials such as copper into the trench 502. A bottom end of TSV 304 is not exposed until the substrate portion 100 is thinning down by polishing or grinding operations employed from the back side 100B thereof afterward.

After the via filling operation, a CMP operation may be implemented to the top surface of the wiring portion 102 to form a flat surface prior to forming the interconnect portion 300 over the wiring portion 102. Furthermore, since the capacitor structure 106 embedded in the wiring portion 102 have to be electrically connected as well, at least a via etching operation and a via filling operation may be implemented to form the first metal contact 118 and the second metal contact 120 over the capacitor structure 106. The aforementioned CMP operation may be implemented after both the TSV 304, the first metal contact 118, and the second metal contact 120 are formed.

Referring to FIG. 11D, the interconnect portion 300 is subsequently formed over the wiring portion 102. The forming of the interconnect portion 300 may include a plurality of interlayer dielectric (ILD) layers, metal layers, and metal vias formed by the BEOL process. The first metal layer 302 of the interconnect portion 300 may be electrically coupled to the TSV 304 and the capacitor structures 106 through the BEOL process.

Next, referring to FIG. 11E, a bumping operation may be implemented at the top surface of the interconnect portion 300 to form the first conductive terminal 306. In some embodiments, the first conductive terminal 306 may include a plurality of conductive pillars (e.g., Cu pillars) or other suitable forms of bumping connections. In some embodiments, the first conductive terminal 306 further includes an under bump metallization (UBM) 310 below the bumping connections. By using the first conductive terminal 306, both the TSVs 304 and the capacitor structures 106 are incorporated into the electrically conductive path extending to a front side 30A of the interposer structure 30. The TSVs 304 and the capacitor structures 106 can be electrically connected to the semiconductor dies 80 in the following packaging operations.

Referring to FIG. 11F, prior to bonding the semiconductor dies 80 to the interposer structure 30, a TSV reveal operation may be implemented and so that the substrate portion 100 is thinned downed from the back side 100B of the substrate portion 100 to expose an end 304a of the TSV 304. Subsequently, as shown in FIG. 11G, a reflow operation may be implemented at the back side 100B of the substrate portion 100 to form the second conductive terminal, such as a C4 bump 312. In such embodiment, the C4 bump 312 is in contact with a UBM 314 that disposed on the back side 100B of the substrate portion 100.

Afterward, as shown in FIG. 11H, a 2.5D assembly operation may be implemented to bond the semiconductor dies 80 at the front side 30A of the interposer structure 30, and the package substrate 90 at a back side 30B of the interposer structure 30 (same as the back side 100B of the substrate portion 100). The package substrate 90 may further include a plurality of solder balls 901 at a back side 90B thereof.

In other embodiments that the interposer structure 10 includes the first capacitor electrode structure 124A in contact with the uncovered region 122 of the bottom metal plate 108 and the second capacitor electrode structure 124B in contact with the top surface of the top metal plate 110, as previously shown in FIG. 6, the operations for manufacturing the interposer structure that packaged with the semiconductor dies 80 and package substrate 90 is almost identical to those previously shown in FIGS. 11A to 11H.

In the embodiments that the TSV 304 penetrates the substrate portion 100, the wiring portion 102, and the interconnect portion 300 (i.e., the embodiments previously shown in FIGS. 9B and 9D), the via etching operation and the via filling operation for forming the TSV 304 may be implemented after the interconnect portion 300 is formed.

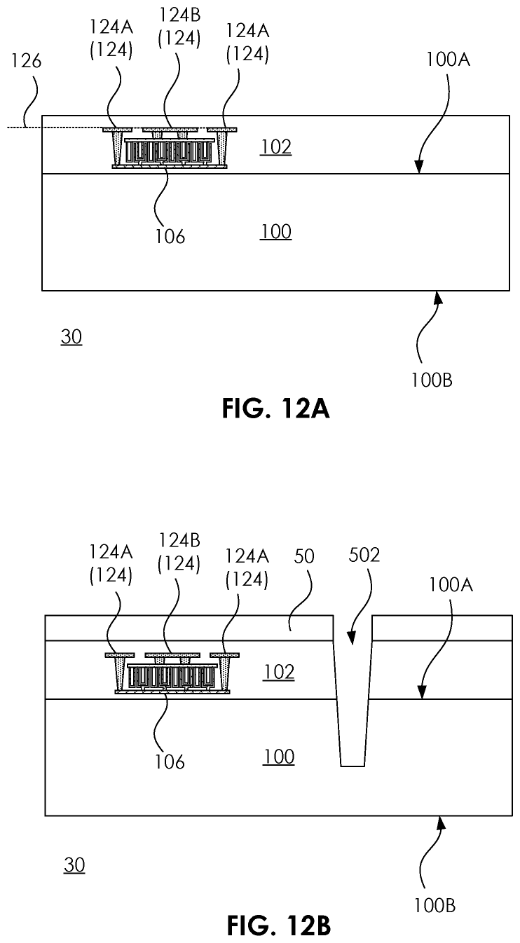

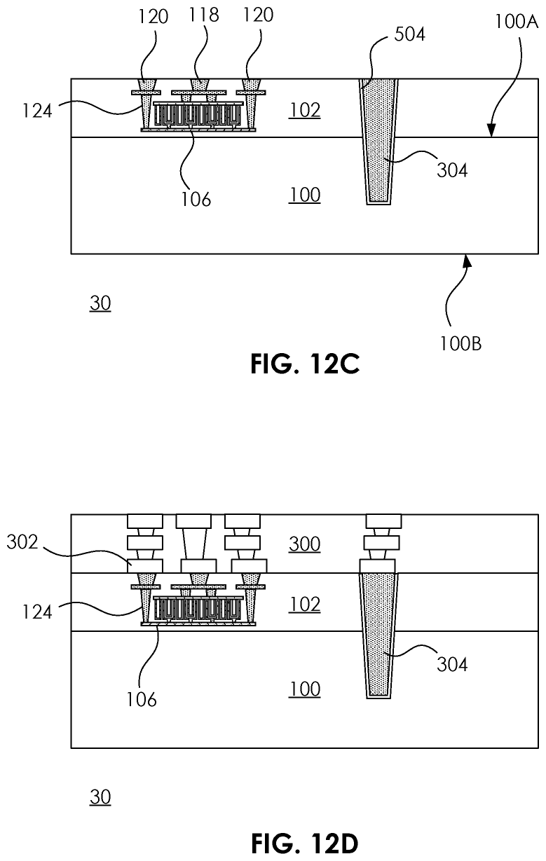

As shown in FIGS. 12A to 12D, in the circumstances that the capacitor structure 106 having the first capacitor electrode structure 124A and the second capacitor electrode structure 124B thereon, the via etching operation and the via filling operation are still implemented to form the first metal contact 118 and the second metal contact 120 over the capacitor structure 106, while such operation per se is easier since the first capacitor electrode structure 124A and the second capacitor electrode structure 124B may provide the coplanar contacting surface 126 over the capacitor structure 106 for the contact landing of the metal contacts, and the first capacitor electrode structure 124A may provide a larger top area to make the landing of the first metal contact 118 easier, and the yield of the product can be improved. The rest of the operations in manufacturing the interposer structure that packaged with the semiconductor dies 80 and package substrate 90 is identical to those previously shown in FIGS. 11A to 11H and omitted here for brevity.

Briefly, the present disclosure provides an interposer structure having 3D capacitors in the MEOL structure thereof. By effectively using the spaces of the interposer structure, a vast number of capacitors may be added to the 2.5D packaged structure. Furthermore, comparing with adding capacitors in other spaces of the 2.5D packaged structure, the position of the MEOL structure in the interposer structure is pretty close to the bonded semiconductor dies such as SOCs, and therefore these capacitors are more effective in minimizing parasitic resistance and inductance.

In one exemplary aspect, an interposer structure is provided. The interposer structure includes a substrate portion, a wiring portion, an interconnect portion, a through via, and a capacitor structure. The wiring portion is disposed over the substrate portion. The interconnect portion is disposed over the wiring portion. The interconnect portion is disposed over the wiring portion. The through via penetrates the substrate portion and the wiring portion. The capacitor structure is embedded in the wiring portion. The interconnect portion includes a first metal wire electrically coupled to the capacitor structure.

In another exemplary aspect, an interposer structure is provided. The interposer structure includes a plurality of interposer units in an array arrangement from a top view perspective. Each of the interposer units includes a first region and a plurality of second regions. The first region has a capacitor structure. Each of the plurality of second regions is free of the capacitor structure. The first region surrounds the plurality of second regions.

In yet another exemplary aspect, a method for manufacturing an interposer structure is provided. The method includes the operations: A wiring portion is formed over a front side of a substrate portion. A plurality of capacitor structures are formed within the wiring portion during forming the wiring portion. And the capacitor structures are formed by a DRAM process.

The foregoing outlines structures of several embodiments so that those skilled in the art may better understand the aspects of the present disclosure. Those skilled in the art should appreciate that they may readily use the present disclosure as a basis for designing or modifying other operations and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An interposer structure, comprising:
a substrate portion;
a wiring portion over the substrate portion;
an interconnect portion over the wiring portion;
a through via penetrating the substrate portion and the wiring portion; and
a capacitor structure embedded in the wiring portion;
wherein the interconnect portion comprises a first metal wire electrically coupled to the capacitor structure.

2. The interposer structure of claim 1, wherein the first metal wire is disposed over the through via, and the first metal wire is electrically coupled to the through via and the capacitor structure.

3. The interposer structure of claim 1, wherein the through via penetrates the substrate portion, the wiring portion, and the interconnect portion, and the through via is disconnected from the first metal wire.

4. The interposer structure of claim 1, wherein the interconnect portion is configured to bond with a first semiconductor die, and the substrate portion is configured to bond with a package substrate.

5. The interposer structure of claim 4, wherein the interconnect portion is further configured to bond with a second semiconductor die, the interconnect portion further comprises a second metal wire electrically connected to the first semiconductor die and the second semiconductor die.

6. The interposer structure of claim 5, wherein the second metal wire is disconnected from the first metal wire or the through via.

7. The interposer structure of claim 1, wherein the substrate portion is composed of semiconductor or insulator.

8. The interposer structure of claim 1, wherein each of the capacitor structures comprises:
a bottom metal plate;
a top metal plate over the bottom metal plate; and
a plurality of capacitor cells between the bottom metal plate and the top metal plate.

9. The interposer structure of claim 8, wherein each of the capacitor cells comprises:
a first conductor film, comprising:
a first portion connected to the bottom metal plate; and
a second portion connected to the first portion and extending toward the top metal plate from the bottom metal plate; and
a second conductor film adjacent to the first conductor film and connected to the top metal plate and extending toward the bottom metal plate from the top metal plate;
wherein the second conductor film is vertically interleaving with the second portion of the first conductor film.

10. The interposer structure of claim 8, further comprising:
a first contact connecting a first metal layer of the interconnect portion and the top metal plate; and
a second contact connecting the first metal layer and the bottom metal plate;
wherein the first contact and the second contact are substantially identical in vertical lengths.

11. The interposer structure of claim 8, further comprising:
a first contact connecting a first metal layer of the interconnect portion and the top metal plate; and
a second contact connecting the first metal layer and the bottom metal plate;
wherein the first contact and the second contact are different in vertical lengths.

12. The interposer structure of claim 8, wherein a distance between the bottom metal plate and the top metal plate is in a range of from about 1 μm to about 2 μm.

13. The interposer structure of claim 1, further comprising:
a memory structure in the wiring portion.

14. An interposer structure, comprising:
a plurality of interposer units in an array arrangement from a top view perspective, each comprising:
a first region having a capacitor structure; and
a plurality of second regions, each being free of the capacitor structure, the first region surrounding the plurality of second regions.

15. The interposer structure of claim 14, wherein adjacent interposer units are spaced apart by a scribe line.

16. The interposer structure of claim 14, wherein an area ratio of the first region in one of the interposer units is in a range of from about 50% to about 80%.

17. The interposer structure of claim 14, wherein a pitch between adjacent second regions is less than about 100 μm, and a length on a side of one of the interposer units is in a range of from about 0.5 to 1 mm.

18. The interposer structure of claim 14, wherein the second region in each of the interposer units is configured to accommodate a through via penetrating the interposer structure.

19. The interposer structure of claim 14, wherein a height of the capacitor structure is in a range of from about 1 μm to about 2 μm and the capacitor structure is located between a substrate portion and an interconnect portion of the interposer structure from a cross sectional view perspective.

20. A method for manufacturing an interposer structure, the method comprising:
forming a wiring portion over a front side of a substrate portion; and
forming a capacitor structure within the wiring portion during forming the wiring portion;
wherein the capacitor structures are formed by a DRAM process.

21. The method of claim 20, further comprising:
forming a through via penetrating the wiring portion and extending toward the substrate portion, wherein the through via is free from overlapping with the capacitor structure;
forming an interconnect portion over the wiring portion, wherein a first metal layer of the interconnect portion is electrically coupled to the capacitor structure and the through via; and
thinning down the substrate portion from a back side of the substrate portion to expose an end of the through via.

22. The method of claim 20, wherein forming the capacitor structure within the wiring portion comprises:
forming a plurality of capacitor electrode structures coupled to the capacitor structure;
wherein the plurality of capacitor electrode structures comprise a coplanar top surface.

23. The method of claim 22, further comprising:
forming a plurality of metal contacts extending from a top surface of the wiring portion to connect to the capacitor electrode structures; and
forming an interconnecting portion over the wiring portion.

24. The method of claim 20, wherein a height of the capacitor structure is in a range of from about 1 μm to about 2 μm.
